(19) United States
(12) Patent Application Publication
(10) Pub. No.: US 2021/0389436 A1
(43) Pub. Date: Dec. 16, 2021

(54) FEEDBACK CONTROL FOR LIDAR USING PRINCIPLES OF DIRECT ATOMIC VAPOR ABSORPTION

(71) Applicant: Michigan Aerospace Corporation, Ann Arbor, MI (US)

(72) Inventor: Will JOHNSON, Saline, MI (US)

(21) Appl. No.: 17/291,597

(22) PCT Filed: Dec. 6, 2019
(86) PCT No.: PCT/US2019/064918

§ 371 Date: May 5, 2021

Related U.S. Application Data
(60) Provisional application No. 62/776,521, filed on Dec. 7, 2018.

(51) Int. Cl. G01S 7/497; G01S 7/486; G01S 17/10

(52) U.S. Cl. CPC G01S 7/497; G01S 17/10; G01S 7/486

(57) ABSTRACT

A direct detection LIght Detection and Ranging (“LIDAR”) system for instantaneous measurement of target velocity and distance uses principles of dichroic atomic vapor absorption in a closed feedback loop. In one or more embodiments, the system includes a laser light source to transmit laser light toward a target; a Dichroic Atomic Vapor Laser Locking (“DAVLL”) system including a gas cell in a magnetic field, wherein the DAVLL system is coupled to receive the laser light after being reflected by the target and output an error signal that can be used to calculated the relative velocity between the emitter and the target; and a feedback control configured to determine respective gas absorption rates of the LCP and RCP light beams in the gas cell, determine a difference of the respective gas absorption rates, and control the laser light source to adjust the frequency of the transmitted laser light in accordance with the determined ratio.

### CROSS REFERENCE TO RELATED APPLICATIONS

This application is a national stage application filed under 35 U.S.C. § 371, of International Patent Application No. PCT/US2019/058603, filed on Oct. 29, 2019, which claims priority to U.S. Provisional Application No. 62/776,521, filed on Dec. 7, 2018, both which are hereby incorporated by reference in their entireties.

### BACKGROUND OF THE INVENTION

LIght Detection And Ranging (“LIDAR”) systems can be used for optically measuring distance to a target. Some methods require multiple measurements of target position or rely on measuring the Doppler shift of light scattered from the target to determine the radial velocity.

If the relative speed of the target to the LIDAR is to be known, for example, two samples of the target's range separated in time may be taken, with the component of the velocity parallel to the LIDAR laser beam being inferred by the change of the target's position divided by the time interval relative to the velocity of the LIDAR system. Measurement of velocity in this fashion requires multiple measurements of target position, which is not always desirable as the target velocity may change in the time interval between range samples, biasing the measurement. Doppler LIDARs which instantaneously measure the Doppler shift of light scattered from a target do not require multiple measurements to be made separated in time. Instead, Doppler measurements may be made by heterodyning, which produces an electrical signal whose frequency is proportional to the difference in frequency of light scattered from the target to the emitted laser light (known as a local oscillator). Such heterodyne systems are effective, but have drawbacks: for example, the optical tolerances required on the LIDAR systems may be quite high, and low cost manufacturing of systems can be a challenge.

The Scheimpflug principle is a geometric rule that describes the orientation of the plane of focus of an optical system (such as a camera) when the lens plane is not parallel to the image plane. It is commonly applied to the use of camera movements on a view camera. It is also the principle used in corneal pachymetry, the mapping of corneal topography, done prior to refractive eye surgery such as LASIK, and used for early detection of keratoconus. The Scheimpflug principle has also found use in LIDAR development. The principle is named after Austrian army Captain Theodor Scheimpflug, who used it in devising a systematic method and apparatus for correcting perspective distortion in aerial photographs. Normally, the lens and image (film or sensor) planes of a camera are parallel, and the plane of focus (PoF) is parallel to the lens and image planes. If a planar subject (such as the side of a building) is also parallel to the image plane, it can coincide with the PoF, and the entire subject can be rendered sharply. If the subject plane is not parallel to the image plane, it will be in focus only along a line where it intersects the PoF. However, when a lens is tilted with respect to the image plane, an oblique tangent extended from the image plane and another extended from the lens plane meet at a line through which the PoF also passes. With this condition, a planar subject that is not parallel to the image plane can be completely in focus. Scheimpflug (1904) referenced this concept in his British patent; Carpentier (1901) also described the concept in an earlier British patent for a perspective-correcting photographic enlarger. The concept can be inferred from a theorem in projective geometry of Gerard Desargues; the principle also readily derives from simple geometric considerations and application of the Gaussian thin-lens formula.

### SUMMARY OF THE INVENTION

A system is described that leverages a laser frequency locking technique known as Dichroic Atomic Vapor Laser Lock (“DAVLL”) and does not require the local oscillator to be mixed with the light scattered from a target. In accordance with at least one embodiment, a narrow linewidth laser may be held to a desired frequency with closed loop control. An “error signal” in the closed loop system is generated by analyzing a difference in transmission of light that is left hand circularly polarized (LCP) to light which is right hand circularly polarized (RCP). If the frequency of the transmitted laser light drifts from the atomic absorption line center, the gas absorption rate of the LCP light will be absorbed differently from the gas absorption rate of the RCP light. The difference between the gas absorption rate of the RCP light to that of the LCP light may be fed back to the closed loop system to bring the laser frequency back to the desired frequency. When the difference of gas absorption rates is zero, the laser is locked to the gas absorption line. When the difference is different from zero, the laser output needs to be corrected in one frequency direction or the other. The exact value of the difference of the LCP to RCP signals depends on a variety of factors such as the orientation of the magnetic field with respect to the laser beam propagation direction, the strength of the magnetic field, efficiency of coupling of optical signals onto the LCP and RCP detectors, and errors in setup such as optical misalignments etc. For a given design, the ratio of LCP to RCP would be measured and calibrated to relate the difference to frequency offset. The frequency offset measurement was originally employed to generate an error signal that could be used to lock the laser to the gas absorption but the frequency offset can be employed to measure the radial velocity (Doppler frequency) of laser light reflected from a target.

### DESCRIPTION OF DRAWINGS

FIG. 1 illustrates an example of a DAVLL system that may be employed in one or more embodiments described herein.

FIGS. 2a-2b illustrate an example of a DAVLL LIDAR system in accordance with one or more embodiments described herein.

FIG. 3 illustrates an error signal produced by a pulsed laser and a target with selected combinations of laser frequency and target Doppler offset frequency.

FIG. 4 illustrates the implementation of the DAVLL system of the present invention in the Scheimpflug condition.

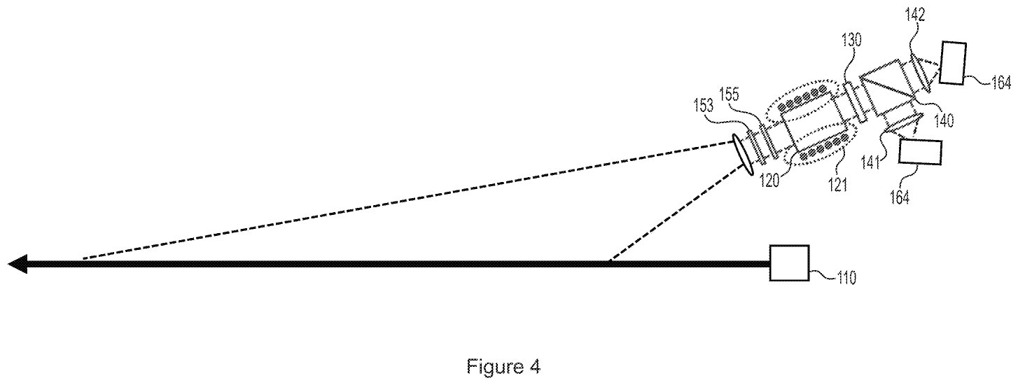

### DETAILED DESCRIPTION OF THE PREFERRED EMBODIMENT

The following description presents one or more embodiments of a direct detection LIDAR system for instantaneous or nearly instantaneous measurement of target speed and distance using features and principles of dichroic atomic vapor absorption.

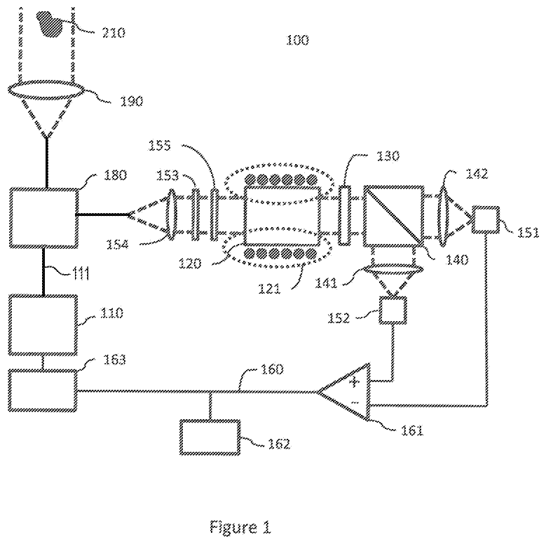

FIG. 1 illustrates an example of a LIDAR system 100 in accordance with at least one embodiment. The illustrated system leverages DAVLL to stabilize a narrow linewidth laser 110 at a desired frequency. As employed in one or more of the embodiments disclosed herein, transmitted light output by laser 110 may be held to a desired frequency with closed loop control. For example, a laser 110 can be passed through a fiber optic circulator 180 which sends the majority of the transmitted laser signal to the transmit/receive optics 190 but also leaks some of the laser 110 signal to the DAVLL gas cell 120. This signal, either from leakage from the circulator 180 or from another optical arrangement where a sample of the laser 110 is collected and directed through the gas cell 120, serves to produce an error signal during operation that is used in a closed loop to keep the laser 110 tuned as close as possible to the center of the gas absorption line.

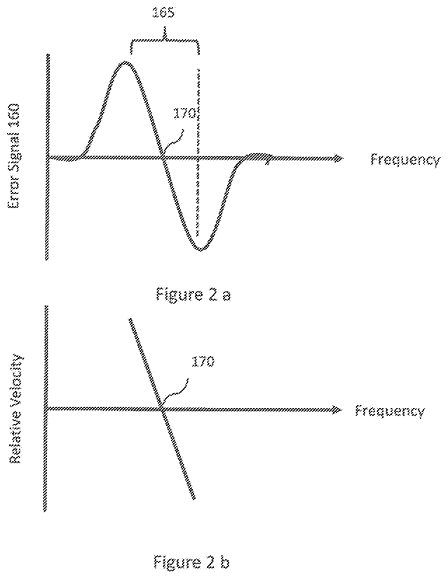

In one or more embodiments, LIDAR system 100 may include a gas cell 120 arranged in a magnetic field to receive the laser beam output by laser 110 which is initially linearly polarized. When an appropriate gas, such as Rubidium, is chosen that has an absorption line that splits due to the Zeeman effect is placed in the magnetic field of the cell, light that is shifted in frequency to one side of the absorption line will have its right hand circularly polarized component get absorbed more strongly than its left hand component and vice versa if the frequency is shifted to the opposite side of the absorption line. A quarter wave plate 130 combined with a polarizing beam splitter 140 separates and outputs beams through optics 142, 141 onto detectors 151 and 152, respectively, that correspond to the left hand and right hand circularly polarized components of the initial laser beam from the laser 110 prior to entering the gas cell 120. The graphs in FIGS. 2a-2b show an error signal 160 (see FIG. 1) generated by the difference between the signals from the detectors 151 and 152 being inputted into a difference amplifier 161 to generate the error signal 160, which is then inputted into a closed loop system in accordance with the difference in the gas absorption rate of laser light of the left hand circularly polarized (LCP) light to that of the right hand circularly polarized (RCP) light. As such, the error signal 160 can be analyzed to indicate a deviation of the laser output frequency from a desired frequency (e.g., the frequency at the atomic gas absorption line center 170 shown in FIGS. 2a-2b) and the corresponding need for an adjustment or “correction” to the frequency of the laser light as indicated by the difference.

Thus, referring to FIGS. 2a-2b, if the frequency of the laser light drifts from its frequency at gas absorption line center 170, the LCP light will be more strongly absorbed than the RCP. The difference of the gas absorption rates of the RCP light to LCP light results in the error signal 160 which may then serve as the feedback signal inputted into the laser drive electronics 163 in a closed loop system (FIG. 1). That is, when the gas absorbs the LCP and RCP components of the light equally, the laser 110 is considered to be “locked” to the frequency at gas absorption line center 170. When the gas absorbs the LCP or RCP components more strongly depending on the laser frequency, the feedback control resulting from the error signal 160 being used as a feedback signal into the laser drive electronics 163 corrects the laser frequency of the laser 110 in the appropriate direction to bring it once again to the frequency corresponding to the gas absorption line center, as illustrated in FIGS. 2a-2b. Features of one, nonlimiting configuration that may be used in principle for generating an error signal and performing a correction using a DAVLL, in general, are described in Corwin, et al., U.S. Pat. No. 6,009,111, the disclosure of which is incorporated herein by reference in its entirety.

In one or more embodiments, the DAVLL system 100 is configured to be sensitive to frequency changes from less than 1 MHz to hundreds of MHz, which corresponds to the range of Doppler shift frequencies in which light is shifted from targets moving at conventional motor vehicle speeds. In the example embodiment shown in FIG. 1, light outputted by laser transmitter/receiver optics 190 is scattered by a target 210, and a portion of the scattered light is collected by the transmitter/receiver optics 190 where it is then input to the DAVLL system 100 by the circulator 180. In one or more embodiments, the DAVLL system 100 may be contained within the same housing (not shown) as the laser source. In principle, however, a common housing for all components is not necessarily required.

Referring to FIG. 1, the narrow line width frequency laser 110 is controlled by the laser drive electronics 163 based on the error signal 160 as a feedback control signal. The laser beam 111 is directed to the circulator 180 where the laser beam is directed to the transmit/receive optics 190. If a target 210 is illuminated by the transmitted light from the laser transmitter/receiver optics 190, some of that light will be reflected and collected by the transmit/receive optics 190 and directed to the circulator 180 to a collimating lens 154 that collimates the light. Following the collimating lens 154 is a polarizer 153 and a narrow bandpass filter 155. The narrow bandpass filter is used to reduce background illumination. The light then goes through the gas cell 120. The gas cell 120 is inside a magnetic field 121 that is produced by magnets 122. The magnets 122 could be either conventional or electro magnets with the electro magnets having the option of changing the magnetic field strength by varying the current to the electro magnets. Light that is not absorbed by the gas cell 120 goes to the quarter wave plate 130 and then on to the polarizing beam splitter 140. The corresponding outputs of the polarizing beam splitter 140 are then focused by lenses 142 and 141 onto detectors 151 and 152, respectively. Detectors 151 and 152 convert the respective light signals to electrical signals that go to the difference amplifier 161. The output of the difference amplifier 161 is the error signal 160 that is sent to the laser drive electronics 163 and the range and velocity computation system 162.

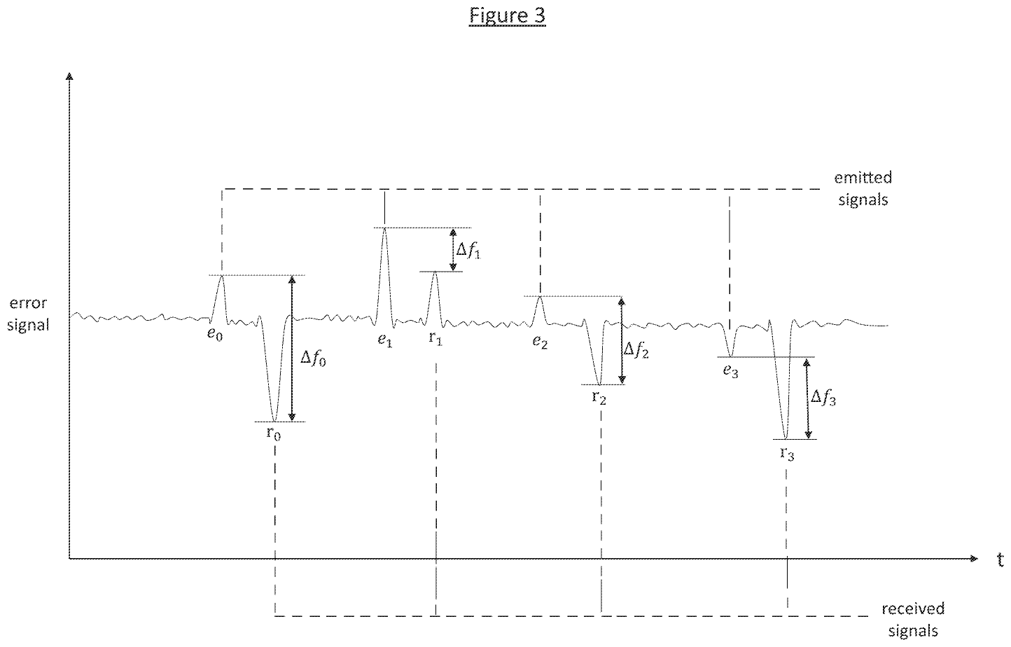

As noted above, FIGS. 2a-2b illustrate graphically a relationship between the error signal 160 and the relative velocity of the target 210. FIG. 2a plots error signal 160 vs. frequency offset from laser line center of a signal passing through the system 100. For a measured error signal, FIG. 2a provides the relationship between the error signal 160 and the offset frequency which for a transmitted laser 110 locked onto the line center of the error signal 160 scattered from a target, can be converted through FIG. 2a to a Doppler shift from the target induced by relative motion between the target and the emitter. FIG. 2b illustrates a portion of the error signal 160 that is single valued 165 that provides an unambiguous relationship between error signal 160 and Doppler shift which can then be converted to relative velocity via Δv=λ*Δf where Δv is the component of the relative velocity between the emitter and the target along the laser beam axis, λ is the laser wavelength, and Δf is the change in frequency calculated using FIG. 2a to convert the measured error to a frequency offset. Once the laser 110 is locked to a gas absorption line (frequency), the light scattered from target 210 can be transmitted through the same gas cell 120. The error signal 160 from the difference of the RCP to LCP signals scattered from the target 210 is related to the relative speed of the target 210 to the LIDAR system 100. If calibrated properly, this difference combined with the time of flight of the return signal from target 210 provides instantaneous or nearly instantaneous information about the distance to target 210 as well as its component of its velocity along the LIDAR beam. An example of what an error signal vs time for the embodiment in FIG. 1 with a pulsed laser 110 is shown in FIG. 3. For one laser pulse emitted, a portion of the outgoing laser pulse is sent through the gas cell assembly and an error signal e₀ is produced. A signal r₀ from a scattering target is measured a time later depending on the distance to the target 210 is also measured. The difference in the error signal for e₀ and r₀ corresponds to a difference in frequency Δf₀ which is then used for relative velocity calculations as discussed earlier. Thus, with a single pulse, the time of flight between e₀ and r₀ and the Δf provides simultaneous ranging and velocity measurements of a target 210. Multiple laser pulses are emitted (e₁, e₂, e₃) and received (r₁, r₂, r₃) over time. The laser center frequency per pulse can be actively locked with the emitted error signals vs. time, and the Δf per pulse can be used to record the target relative component velocities vs. time.

In another embodiment, the laser light scattered from targets along the beam is imaged through the gas cell assembly onto two camera detectors 164. In this arrangement, the laser beam from the laser 110 is put in focus at all ranges by tilting the camera detectors 164 into the Scheimpflug condition. A calibration of the instrument maps the pixel on the camera detectors 164 to a distance from at least the transceiver of the LIDAR system 100. The camera detectors may be implemented using line cameras, CCDs or other detector arrays (e.g., 1D or 2D arrays) known in the art. All other elements of the present invention not otherwise mentioned for purposes of this embodiment remain the same in structure and function. For a given distance, the pixel intensity on each camera pixel corresponding to the LHP and RHP signals is analyzed to compute the error signal and thus the Doppler shift. In this embodiment, continuous wave lasers can be used in place of higher priced pulsed lasers, and line cameras can measure the backscattered intensity instead of more costly high speed photodetectors such as photomultiplier tubes.

Embodiments of a LIDAR system have been described in the context of a target speed detector that does not require multiple measurements of target position or mixing of light scattered from the target with emitted laser light. Such advantages are merely illustrative and the disclosed embodiments may enjoy one or more of these advantages as well as other advantages. Moreover, the disclosed LIDAR system is not limited to detecting any particular type of target, but may be used to detect targets of various size, shape, composition, and/or velocity.

Various changes and modifications to the disclosed LIDAR system will be apparent to those skilled in the art. All such changes and modifications that rely on the basic teachings and principles through which the invention has advanced the state of the art are to be understood as included within the spirit scope of the present invention.

What is claimed is:

1. A LIDAR system, comprising:
a laser light source to transmit laser light toward a target;
a DAVLL system including a gas cell in a magnetic field, wherein the DAVLL system is coupled to receive the laser light after being reflected by the target and output an error signal related to the frequency offset between the transmitting laser and the gas absorption line center and the frequency offset between the received light from a target and the gas absorption line center; and
a feedback control configured to determine respective gas absorption rates of the LCP and RCP light beams in the gas cell, determine a difference of the respective gas absorption rates, and control the laser light source to adjust the frequency of the transmitted laser light in accordance with the determined ratio.

2. The LIDAR system of claim 1, further comprising a processor configured to compute a speed of the target in accordance with the determined ratio.

3. The LIDAR system of claim 2, wherein the processor is further configured to compute a distance to the target in accordance with the determined ratio.

4. The LIDAR system of claim 1, wherein the feedback control is configured to control the laser light source to adjust the frequency of the transmitted laser light to the frequency at the gas absorption line center.
